(19) United States
(12) Patent Application Publication
(10) Pub. No.: US 2008/0191944 A1
(43) Pub. Date: Aug. 14, 2008

(54) Method For Establishing an Electrical and Mechanical Connection Between Chip Contact Surfaces and Antenna Contact Surfaces and Transponder

(75) Inventor: Volker Brod, Bad Abbach (DE)

Correspondence Address: NEEDLE & ROSENBERG, P.C., SUITE 1000, 999 PEACHTREE STREET, ATLANTA, GA, 30309-3915, US

(73) Assignee: MUHLBAUER AG, Roding (DE)

(21) Appl. No.: 11/885,907

(22) PCT Filed: Mar. 8, 2006
(86) PCT No.: PCT/EP06/60536

§ 371 Date: Sep. 7, 2007

(30) Foreign Application Priority Data
Mar. 9, 2005 (DE) 10 2005 011 186.6
Apr. 13, 2005 (DE) 10 2005 016 930.9

(51) Int. Cl. H01L 21/50; H01Q 1/38

(52) U.S. Cl. 343/700 MS; 438/108; 257/E21.499

(57) ABSTRACT

The invention relates to a method for establishing an electrical and mechanical connection between chip contact surfaces of an RFID chip and contact surfaces arranged on a strip-like substrate, wherein the chip contact surfaces which have on their surfaces a plurality of thread-like hooks and/or thread-like eyes are hooked together, under the effect of pressure, with the associated contact surfaces which have on their surfaces a plurality of thread-like eyes and/or thread-like hooks. A transponder is shown.

The invention relates to a method for establishing an electrical and mechanical connection between chip contact surfaces of an RFID chip and contact surfaces arranged on a strip-like substrate, according to the preamble of claim 1, and also to a transponder comprising at least one RFID chip and at least one RFID antenna which is arranged on a strip-like substrate, according to the preamble of claim 10.

Semiconductor chips, also known as bare dice, such as RFID chips for example, are conventionally connected to electrical circuits, such as RFID antennas for example, which are arranged continuously on a strip-like, usually flexible substrate, by means of adhesive, solder and/or bump-type bonds in order to obtain a functional transponder for example for producing smart labels. Such types of connection are time-consuming to produce and often require stoppage of the continuously movable strip-like substrate. Moreover, in order to apply for example adhesives or solder materials and subsequently cure them, additional devices arranged along the substrate strip are required, such as a thermode curing station, which are expensive to provide and take up a lot of space within the overall system.

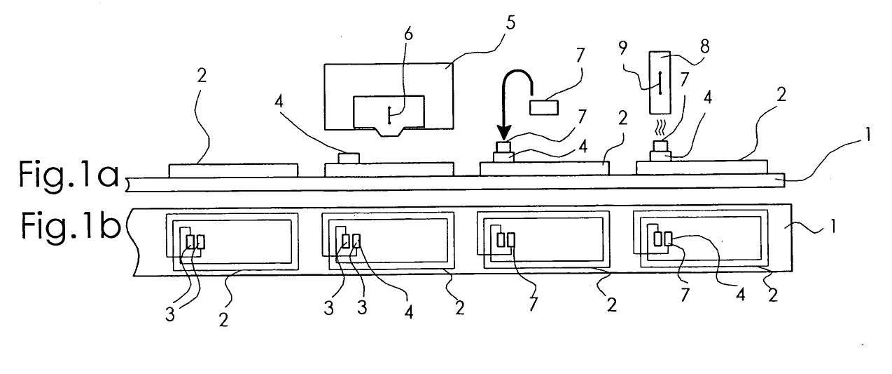

This is illustrated with reference to FIGS. 1a and 1b based on the example of the flip-chip method considered in combination with the conventional connection mode of adhesive bonding. In the flip-chip method, the mounting of RFID chips and the connection of their chip contact surfaces to contact surfaces of the antennas 2 arranged in rows on the strip-like substrate 1 is split into several process steps. FIG. 1a shows a schematic side view in which the strip-like substrate, which on the left side is unwound from a roll (not shown here) and on the right side is rolled up onto a roll (not shown here), moves from left to right. Firstly, the antennas 2 are applied in loop form to the substrate, for example by means of a printing method, as can be seen by looking also at FIG. 1b which shows a plan view of the conventional mounting process shown in FIG. 1a.

The antennas 2 have at their end two contact surfaces 3 which in a second process step are covered with a preferably electrically conductive adhesive 4. For this, an adhesive application device 5 is used which applies a predetermined quantity of adhesive, as represented by the double arrow 6.

In a third process step, using the known flip-chip method a chip 7 is placed upside-down on the adhesive area 4 and is pressed onto the latter. Then, in a fourth process step, curing of the adhesive takes place under the application of heat by a curing device 8 which is vertically displaceable as shown by the double arrow 9.

In such conventional connection methods, the strip-like substrates 1 are usually briefly stopped at each process step, with the length of this stoppage of the substrate strip 1 depending primarily on the curing times of the adhesives used and the speed of the flip-chip device when transferring the chip 7 to the adhesive area 4, in particular during the associated pick-and-place method.

However, a relatively long stoppage of the substrate strip considerably reduces the maximum possible throughput of the overall system for producing transponders.

Accordingly, the object of the present invention is to provide a method for establishing an electrical and mechanical connection between chip contact surfaces of an RFID chip and contact surfaces arranged on a strip-like substrate, and also a transponder, in which fast and simple connection is possible, wherein a high throughput of a device implementing this method is to be ensured.

This object is achieved in terms of the method by the features of claim 1 and in terms of the product by the features of claim 10.

One essential point of the invention consists in that, in a method for establishing an electrical and mechanical connection between chip contact surfaces of an RFID chip and contact surfaces arranged on a strip-like substrate, these chip contact surfaces which have on their surfaces a plurality of thread-like hooks and/or thread-like eyes are hooked together, under the effect of pressure, with the associated contact surfaces which have on their surfaces a plurality of thread-like eyes and/or thread-like hooks. The thread-like hooks and eyes are preferably formed with a size in the nanometre range, as a result of which precise positioning of the individual chip contact surfaces and contact surfaces with respect to one another is possible. It is thus possible in a simple manner to quickly establish a mechanical and electrical connection between the chip contact surfaces and the contact surfaces arranged on the substrate, which may belong to an electrical circuit, such as an RFID antenna for example, without requiring any stoppage of the continuously moving substrate strip.

Although a brief stoppage of the substrate strip is still necessary when employing the flip-chip method using the connection method according to the invention, this stoppage time can be reduced to a minimum since there is no need for subsequent adhesive curing process steps.

As the material for the thread-like hooks and thread-like eyes, use is made of electrically conductive threads or of electrically insulating threads with an electrically conductive coating so as to obtain in addition to the mechanical contact also the electrical contact between the chip contact surfaces and the antenna contact surfaces. There is thus no need for additional connection steps for electrical and/or mechanical contacting, such as an adhesive or solder connection for example.

Advantageously, the semiconductor chips have on their chip contact surfaces either hooks or eyes which are produced in nanotechnology already during chip manufacture. Such chips are then subsequently applied to wafers or arranged in one or several rows on a further strip or a feed device which is angled with respect to the substrate strip, in order to be continuously deposited on the substrate strip in the region of the other antenna contact surfaces.

A roller arranged on the upper side and a roller arranged on the underside in the running direction of the substrate strip then ensure a brief application of pressure between the deposited chip and the substrate, so that the hooks on one surface and the eyes on the other surface are durably hooked together or engage in one another.

The threads may be produced by means of a printing method or by roughening the surface of the chip module contact surface and/or the contact surfaces of the antenna prior to the hooking-together step.

By simply pressing the semiconductor chips onto the contact surfaces and the substrate, both the mechanical and the electrical connection can be established under the effect of force within a very short time and within a common mounting step. This has an advantageous effect on the production of transponders both when using the flip-chip technique, in which each RFID chip is deposited from the wafer onto the contact surfaces and the strip-like substrate and pressed onto the latter so as to hook together while the strip-like substrate is briefly stopped, and when using the continuously moving substrate strip, on which the RFID chips are continuously deposited in a manner arranged one behind the other.

A transponder comprising at least one RFID chip and at least one RFID antenna which is arranged on the strip-like substrate is characterised in that the chip contact surfaces have either the hooks or thread-like eyes and the antenna contact surfaces have the complementary eyes or hooks.

Further advantageous embodiments emerge from the dependent claims.

Advantages and expedient features can be found in the following description in conjunction with the drawing, in which:

FIGS. 1a and 1b show a schematic side view of a mounting method for semiconductor chips according to the prior art;

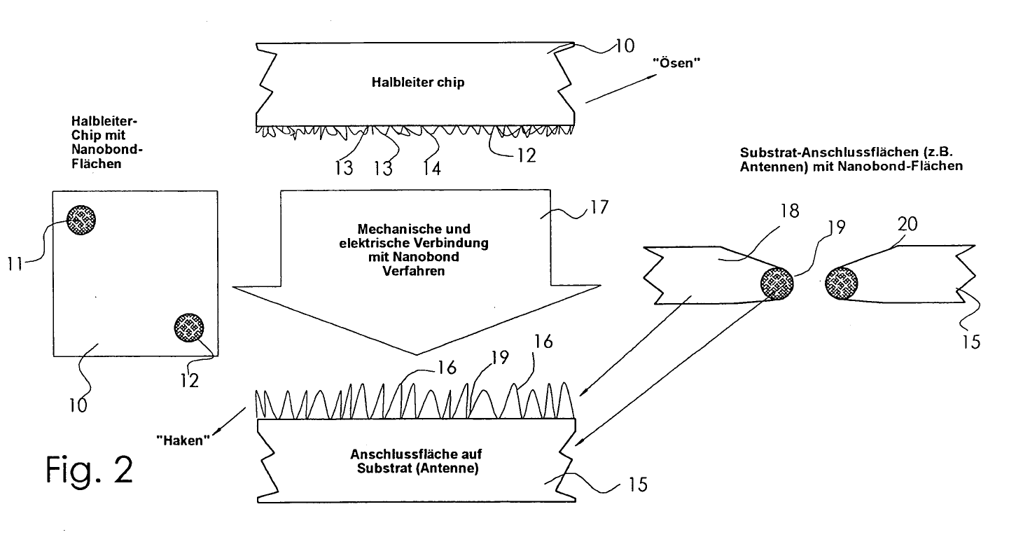

FIG. 2 shows a schematic enlarged view of the method according to the invention;

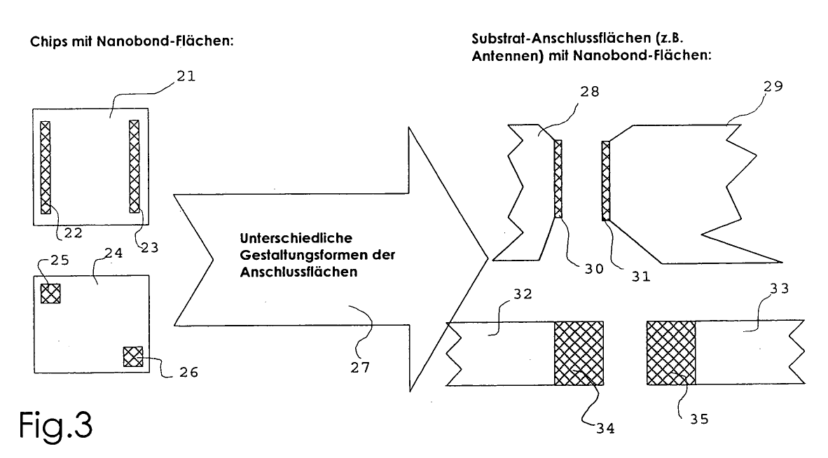

FIG. 3 shows a schematic view of various forms of chip contact surfaces and antenna contact surfaces for carrying out the method according to the invention;

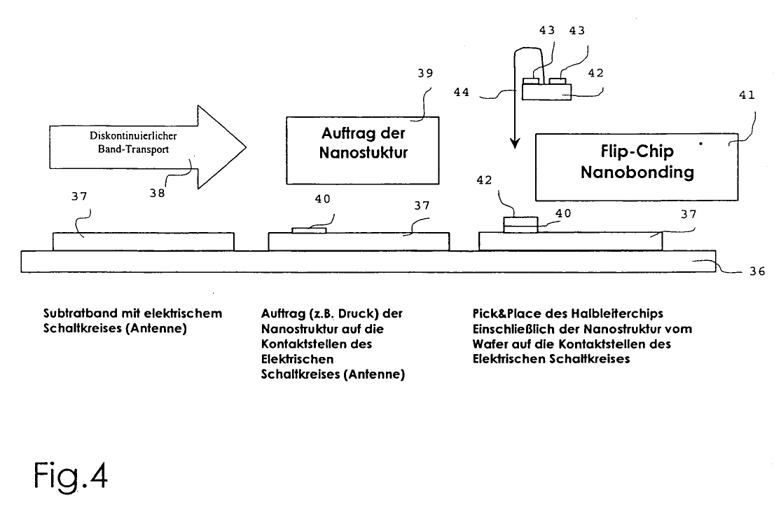

FIG. 4 shows a schematic side view of the connection method according to one embodiment of the invention, and

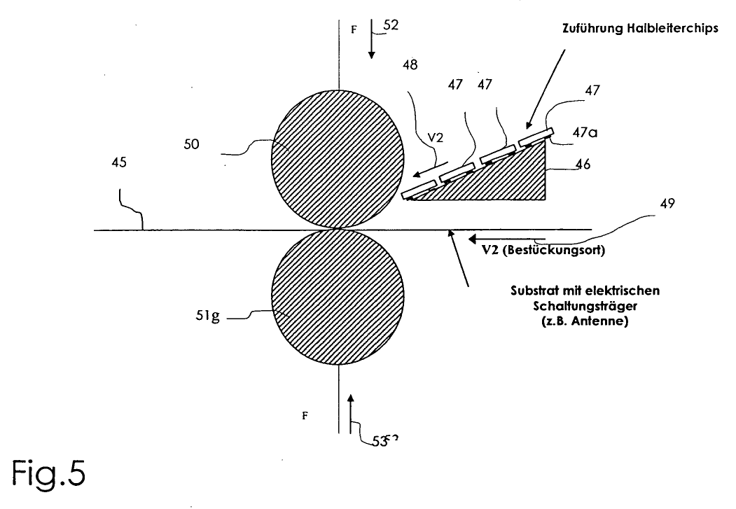

FIG. 5 shows a schematic side view of the connection method according to a further embodiment of the invention.

FIG. 2 shows a schematic view of the connection method according to the invention. A semiconductor chip 10 has point-shaped chip contact surfaces 11, 12 or nanobonding surfaces. These nanobonding surfaces 11, 12 are provided with thread-like eyes 13, 14 which have a size in the nanometre range.

The thread-like eyes 13 preferably consist of electrically conductive threads, such as metal threads 14, or electrically insulating threads with an electrically conductive coating.

A substrate strip (not shown here) has an antenna 15, 18, sections of which are shown here. The antenna sections 15, 18 are provided at their ends with nanobonding surfaces or antenna contact surfaces 19, 20 which are shown in an enlarged view. It can be seen from the enlarged view that the antenna contact surface 19 has hooks 16 consisting of metal threads or of electrically insulating threads with an electrically conductive coating. These hooks 16 engage in the eyes 13 when the semiconductor chip 10 and the antenna of the antenna section 15 are joined together, and establish both a mechanical and an electrical connection in a so-called nanobonding method, as illustrated by the reference 17.

FIG. 3 shows a schematic view of various chip contact surfaces and antenna contact surfaces. A chip 21 may have for example two strip-like chip contact surfaces 22, 23 with a hook-type or eye-type surface structure according to the invention. Alternatively, a chip 24 may have very small rectangular chip contact surfaces 25, 26 with the hook-type or eye-type surface structures.

Reference 27 shows that such different types of chip contact surfaces engage with different types of antenna contact surfaces. By way of example, antenna sections 28, 29 may also have at their ends strip-like contact surfaces 30, 31 which are provided with hooks or eyes. Alternatively, antenna sections 32, 33 have rectangular nanobonding surfaces 34, 35 for association with the chip contact surfaces 25, 26.

FIG. 4 shows a schematic side view of a connection method according to one embodiment of the invention. This connection method comprises the flip-chip method, wherein a substrate strip 36 with RFID antennas 37 arranged thereon is moved discontinuously, i.e. with brief stoppages, from left to right as shown by reference 38.

A nanostructure, i.e. thread-like hooks or thread-like eyes, is applied by means of an application device 39 to each RFID antenna 37 in the region of the antenna contact surfaces. This region is represented by reference 40.

In the subsequent flip-chip method 41, a chip 42 with eye-like or hook-like threads 43 already arranged thereon is removed from a wafer (not shown here) and turned over, as represented by reference 44.

The chip 42 with its chip contact surfaces 43 arranged on the underside is then deposited on the antenna contact surfaces 40, which have the necessary nanostructure on their surface, and briefly pressed down so that a durable mechanical and electrical connection is established between the chip contact surfaces 43 and the antenna contact surfaces 40.

While equipping the antenna 37 with the chip 42, the substrate strip 36 is briefly stopped. There is no need for the curing process which is necessary in the prior art.

FIG. 5 shows a schematic side view of the connection method according to a further embodiment of the invention. The connection method shown in this figure allows very fast equipping of the antennas with the chips, since a substrate strip 45 can be moved continuously.

By means of a plane of a feed unit 46 which is angled with respect to the substrate plane, chips 47 are fed to the substrate strip in one or several rows. For this, the chips are fed at a speed 48 which corresponds to a speed 49 of the substrate strip 45. The chips 47 have on their underside the threads already formed as hooks or eyes in the region of the chip contact surfaces 47a.

The feed unit 46, also referred to as the chip feeder, may consist for example of a blister tape, surf tape, chip shooter or vibrority assembly feeder.

After feeding of the chips 47, each chip 47 runs through rollers 50, 51 arranged on the upper side and underside of the substrate strip 45, which rollers exert a force 52, 53 on the chips 47 and the substrate strip with the antennas (not shown here) arranged thereon, in order to durably hook together the chip contact surfaces and the contact surfaces of the antennas.

All the features disclosed in the application documents are claimed as essential to the invention in so far as they are novel individually or in combination with respect to the prior art.

### LIST OF REFERENCES

1, 36, 45 substrate strip
2, 15, 18, 28, 29, 32, 33, 37 antenna
3, 19, 20, 30, 31, 34, 35 antenna contact surface
4 adhesive
5 adhesive application device
6 movement direction of the adhesive application device
7, 10, 21, 24, 42, 47 semiconductor chip
8 curing device
9 movement direction of the curing device
11, 12, 22, 23, 25, 26, 43, 47a chip contact surfaces
13 thread-like eyes
14 threads
16 thread-like hooks
17 mechanical and electrical connection
27 association of the contact surfaces
38 movement direction of the discontinuous strip transport
39 application of the nanostructure
40 nanostructure
41 flip-chip nanobonding
44 turning-over of the chip
46 feed unit
48, 49 speeds
50, 51 rollers
52, 53 exertion of force

1. Method for establishing an electrical and mechanical connection between chip contact surfaces of an RFID chip and contact surfaces arranged on a strip-like substrate, characterised in that the chip contact surfaces which have on their surfaces a plurality of thread-like eyes and/or thread-like hooks are hooked together, under the effect of pressure, with the associated contact surfaces which have on their surfaces a plurality of thread-like hooks and/or thread-like eyes.

2. Method according to claim 1, characterised in that, prior to the hooking-together step, RFID antennas with the contact surfaces are applied to the strip-like substrate.

3. Method according to claim 1, characterised in that electrically conductive threads are used as the material for the thread-like hooks and the thread-like eyes.

4. Method according to claim 1, characterised in that electrically insulating threads with an electrically conductive coating are used as the material for the thread-like hooks and the thread-like eyes.

5. Method according to claim 3, characterised in that the threads are applied by means of a printing method to the chip contact surfaces and to the contact surfaces prior to the hooking-together step.

6. Method according to claim 1, characterised in that the thread-like hooks are produced prior to the hooking-together step by roughening the surfaces of the chip module contact surfaces and/or the contact surfaces.

7. Method according to claim 1, characterised in that the thread-like hooks and eyes are produced with a size in the nanometre range.

8. Method according to claim 1, characterised in that each RFID chip is deposited from a wafer onto the contact surfaces and the strip-like substrate using the flip-chip technique and is pressed on so as to hook together while the strip-like substrate is stationary.

9. Method according to claim 1, characterised in that the RFID chips are deposited continuously on the strip-like substrate in a manner arranged one behind the other and assigned to the contact surfaces, while the strip-like substrate continues to move continuously.

10. Transponder comprising at least one RFID chip and at least one RFID antenna which is arranged on a strip-like substrate, characterised in that chip contact surfaces have on their surfaces a plurality of thread-like eyes and/or thread-like hooks which engage in a plurality of thread-like hooks and/or thread-like eyes arranged on surfaces of antenna contact surfaces.

11. Transponder according to claim 10, characterised in that the thread-like hooks and eyes are electrically conductive threads.

12. Transponder according to claim 10, characterised in that the thread-like hooks and eyes are electrically insulating threads with an electrically conductive coating.
